(19) United States
(12) Patent Application Publication
(10) Pub. No.: US 2026/0040545 A1
(43) Pub. Date: Feb. 5, 2026

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventors: Rho Gyu KWAK, Icheon-si Gyeonggi-do (KR); In Su PARK, Icheon-si Gyeonggi-do (KR); Na Yeong YANG, Icheon-si Gyeonggi-do (KR); Jung Shik JANG, Icheon-si Gyeonggi-do (KR); Seok Min CHOI, Icheon-si Gyeonggi-do (KR); Won Geun CHOI, Icheon-si Gyeonggi-do (KR)

(73) Assignee: SK hynix Inc., Icheon-si Gyeonggi-do (KR)

(21) Appl. No.: 18/917,725

(22) Filed: Oct. 16, 2024

(30) Foreign Application Priority Data
Jul. 30, 2024 (KR) 10-2024-0100691

(51) Int. Cl. H10B 43/27; H10B 41/27

(52) U.S. Cl. CPC H10B 43/27; H10B 41/27

(57) ABSTRACT

A method of manufacturing a semiconductor device includes forming a stack by alternately stacking first material layers and second material layers, forming a separation sacrificial layer extending through the stack, forming channel structures extending through the stack and the separation sacrificial layer, forming a slit extending through the stack, forming first openings by removing the second material layers through the slit, forming a second opening by removing the separation sacrificial layer through the slit, forming third material layers in the first openings through the slit and the second opening, forming a separation structure in the second opening, and forming a slit structure in the slit.

### CROSS-REFERENCE TO RELATED APPLICATION

The present application claims priority under 35 U.S.C. § 119 (a) to Korean Patent Application No. 10-2024-0100691, filed in the Korean Intellectual Property Office on Jul. 30, 2024, which application is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

The integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a method of manufacturing a semiconductor device may include forming a stack by alternately stacking first material layers and second material layers, forming a separation sacrificial layer extending through the stack, forming channel structures extending through the stack and the separation sacrificial layer, forming a slit extending through the stack, forming first openings by removing the second material layers through the slit, forming a second opening by removing the separation sacrificial layer through the slit, forming third material layers in the first openings through the slit and the second opening, forming a separation structure in the second opening, and forming a slit structure in the slit.

According to an embodiment of the present disclosure, a method of manufacturing a semiconductor device may include forming a stack including alternately stacking sacrificial layers and insulating layers, forming a separation sacrificial layer in the stack, forming channel structures extending through the separation sacrificial layer and the stack, forming a slit extending through the stack, forming first openings by removing the sacrificial layers through the slit and forming a second opening by removing the separation sacrificial layer simultaneously, forming a conductive layer filling the first openings and extending into the slit and the second opening, removing a portion of the conductive layer formed on a lower surface of the second opening and a lower surface of the slit, forming a separation structure in the second opening, removing a portion of the conductive layer formed on an inner wall of the slit, and forming a slit structure in the slit.

### BRIEF DESCRIPTION OF THE DRAWINGS

FIGS. 1A, 1B, 1C, and 1D are drawings illustrating a semiconductor device according to an embodiment of the present disclosure.

FIGS. 2A, 2B, 3A, 3B, 4A, 4B, 4C, 4D, 5A, 5B, 5C, 5D, 6A, 6B, 6C, 6D, 7A, 7B, 7C, and 7D are drawings illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

According to the present technology, a semiconductor device having a stable structure and improved reliability may be provided.

Hereinafter, embodiments according to the technical spirit of the present disclosure are described with reference to the accompanying drawings. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Terms such as “first” and “second” are used to distinguish between various elements and do not imply size, order, priority, quantity, or importance of the elements. For example, a first element may be named as a second element in one example, and the second element may be named as a first element in another example. Terms such as “vertical,” “horizontal,” “over,” “side,” “lower,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas.

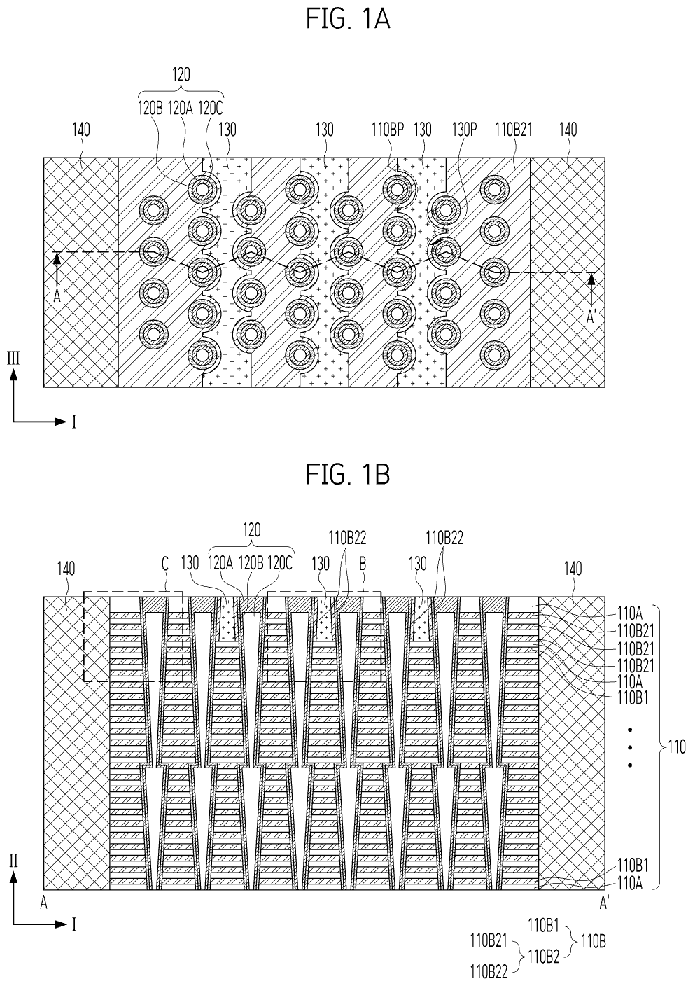

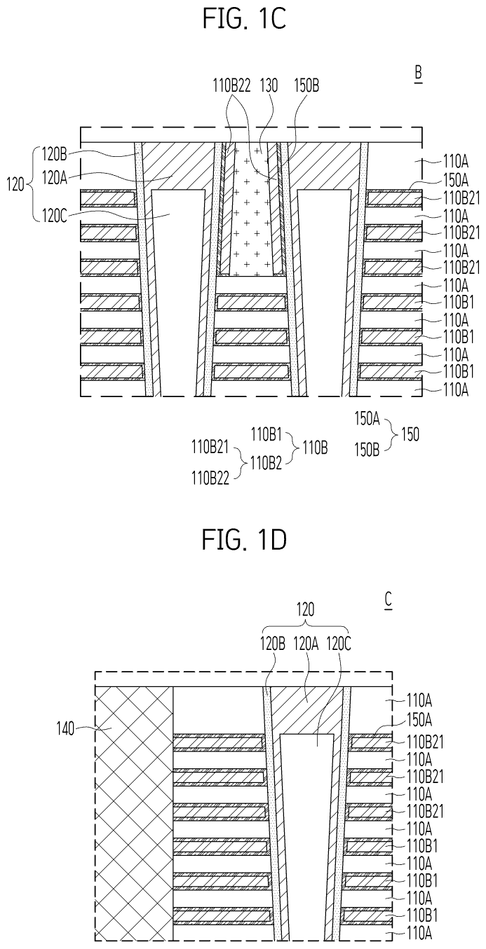

FIGS. 1A to 1D are drawings illustrating a semiconductor device according to an embodiment of the present disclosure. FIG. 1A may be a plan view, FIG. 1B may be an A-A′ cross-sectional view of FIG. 1A, FIG. 1C may be a B enlarged view of FIG. 1B, and FIG. 1D may be a C enlarged view of FIG. 1B.

Referring to FIGS. 1A to 1D, the semiconductor device may include at least one of a gate structure 110, channel structures 120, separation structures 130, and slit structures 140. The semiconductor device may further include barrier layers 150.

Referring to FIGS. 1A and 1B, the gate structure 110 may include alternately stacked insulating layers 110A and conductive layers 110B. Here, at least one conductive layer 110B positioned at the uppermost portion may be a drain select line 110B2, and remaining conductive layers 110B may be a word line 110B1. For reference, although not shown in this drawing, a source select line may be positioned under the word line 110B1.

The word line 110B1 and the drain select line 110B2 may have different shapes. The word line 110B1 may have a plate shape, and the drain select line 110B2 may have a shape in which a horizontal portion 110B21 and a vertical portion 110B22 are combined. The horizontal portion 110B21 may extend along a plane defined by a first direction I and a third direction III. A plurality of horizontal portions 110B21 may be alternately stacked with the insulating layers 110A. The vertical portion 110B22 may extend along a second direction II, and the stacked horizontal portions 110B21 may be connected by the vertical portion 110B22. Here, the second direction II may mean a direction intersecting the first direction I, and the third direction III may mean a direction intersecting the first direction I and the second direction II.

In the plane defined by the first direction I and the third direction III, the drain select line 110B2 may include protrusions 110BP that are successively arranged. For example, the drain select line 110B2 may extend in the third direction III and may include the protrusions 110BP that protrude in the first direction I. The drain select line 110B2 may include sidewalls facing in the first direction I, and may include the protrusions 110BP only on one sidewall, or may include the protrusions 110BP on both sidewalls. The protrusions 110BP and the channel structures 120 may be arranged correspondingly. The protrusions 110BP may respectively surround the channel structures 120. The insulating layer 110A may include an insulating material such as oxide, and the conductive layers 110B may include a conductive material such as tungsten, molybdenum, or polysilicon.

The slit structures 140 may pass through the gate structure 110. For example, the slit structures 140 may extend in the second direction II through the horizontal portions 110B21 of the drain select lines 110B2 and the word lines 110B1 and pass through the gate structure 110. The slit structures 140 may be spaced apart from each other in the first direction I. The slit structures 140 may include at least one of polysilicon, a metal, an insulating material, and a semiconductor material.

The channel structures 120 may be positioned between the slit structures 140. In a plane, the channel structures 120 may be arranged in the first direction I and the third direction III. For example, the channel structures 120 may be arranged to be spaced apart from each other in a diagonal direction. Therefore, when the channel structures 120 are arranged in a parallel manner in the first direction I or the third direction III, a greater number of channel structures 120 may be positioned between the slit structures 140. Here, the diagonal direction may mean a direction between the first direction I and the third direction III.

The channel structures 120 may pass through the gate structure 110. For example, the channel structures 120 may extend in the second direction II through the horizontal portions 110B21 of the drain select lines 110B2 and the word lines 110B1 to pass through the gate structure 110. Each of the channel structures 120 may include a channel layer 120A. Each of the channel structures 120 may further include at least one of a memory layer 120B surrounding the channel layer 120A and an insulating core 120C positioned in the channel layer 120A.

The separation structures 130 may be positioned between the slit structures 140. For example, two or more separation structures 130 may be positioned between the slit structures 140. However, the present disclosure is not limited thereto, and three or more separation structures 130 may be positioned between the slit structures 140. One separation structure 130 may be positioned between a pair of drain select lines 110B2 adjacent in the first direction I. The separation structures 130 may extend in the third direction III and may include protrusions 130P successively arranged on a sidewall facing in the first direction I. The protrusions 130P may protrude between the channel structures 120. Therefore, the protrusions 130P of the separation structures 130 and the protrusions 110BP of the conductive layers 110B may be alternately arranged along the third direction III. The separation structures 130 may include an insulating material. For example, the separation structures 130 may include oxide.

Referring to FIGS. 1C and 1D, the semiconductor device may further include barrier layers 150. The barrier layers 150 may surround the conductive layers 110B. The barrier layer 150 surrounding the drain select line 110B2 may include a horizontal portion 150A and a vertical portion 150B. The horizontal portion 150A may surround a sidewall of the horizontal portion 110B21 of the drain select line 110B2. The vertical portion 150B may surround the vertical portion 110B22 of the drain select line 110B2 and may surround a sidewall of the channel structure 120. Here, the vertical portion 150B may be in contact with the channel structure 120. The barrier layers 150 may be a metal barrier layer. For example, the barrier layers 150 may include metal nitride.

According to the structure described above, three or more separation structures 130 may be positioned between the slit structures 140. The separation structures 130 may include the protrusions 130P that are successively arranged. For example, the protrusions 130P of the separation structures 130 and the protrusions 110BP of the drain select line 110B2 may be alternately arranged along the third direction III.

The drain select lines 110B2 separated by the separation structures 130 may include a horizontal portion 110B21 and a vertical portion 110B22. The horizontal portions 110B21 may be connected by the vertical portion 110B22. Therefore, the drain select lines 110B2 may surround the channel structures 120, and each of the channel structures 120 may be used as one memory string.

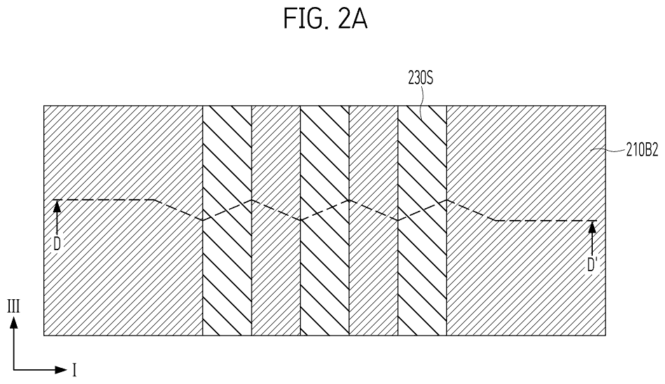

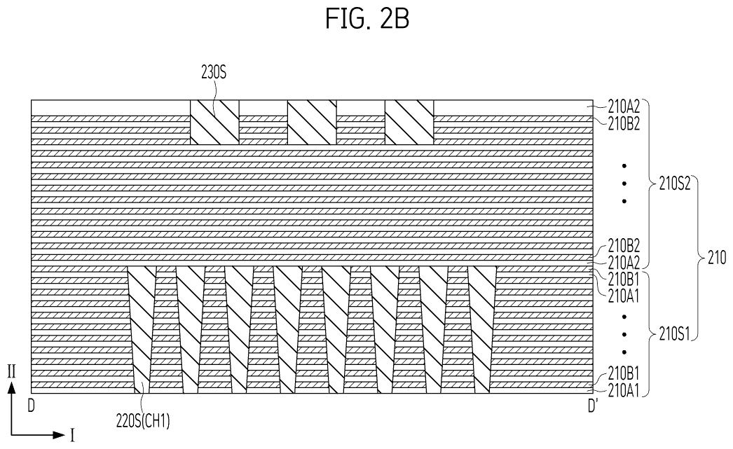

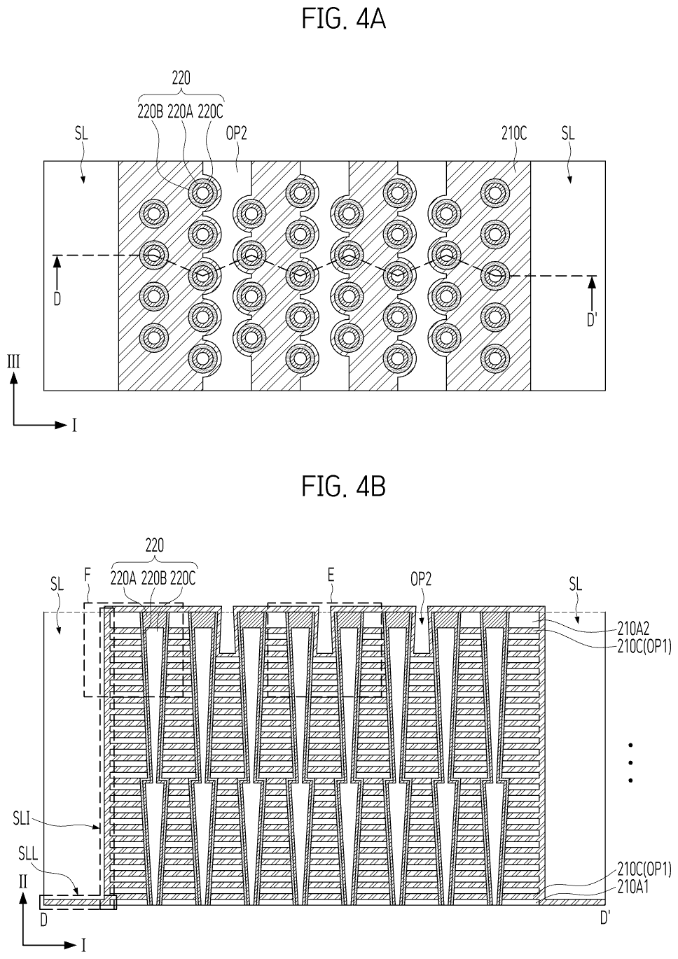

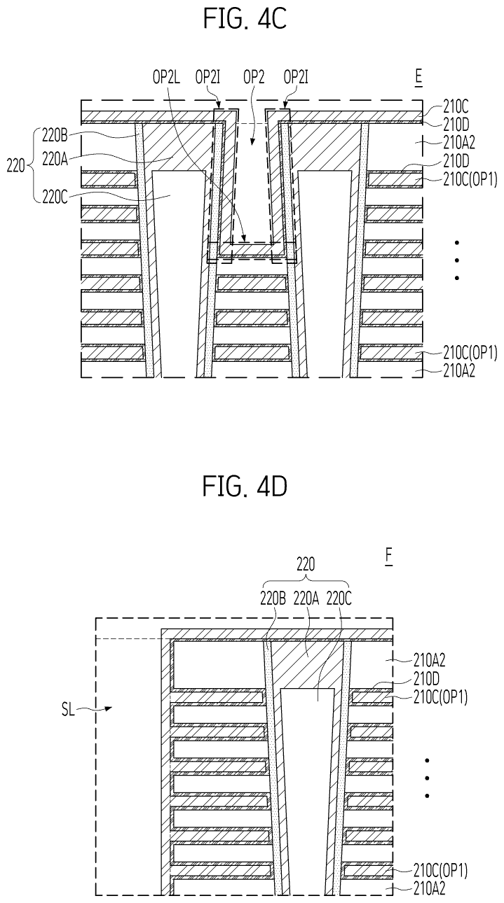

FIGS. 2A to 7B are drawings illustrating a method of manufacturing a semiconductor device according to an embodiment of the present disclosure. FIGS. 2A, 3A, 4A, 5A, 6A, and 7A may be plan views, FIGS. 2B, 3B, 4B, 5B, 6B, and 7B may be D-D cross-sectional views of respective FIGS. A, FIG. 4C, 5C, 6C, and 7C may be E enlarged views respective FIGS. B, and FIG. 4D, 5D, 6D, and 7D may be F enlarged views of respective FIGS. B. Hereinafter, a content overlapping the content described above is omitted.

Referring to FIGS. 2A and 2B, a stack 210 may be formed by alternately stacking first material layers 210A1 and 210A2 and second material layers 210B1 and 210B2. First, a first stack 210S1 may be formed by alternately stacking the first material layers 210A1 and the second material layers 210B1. Next, a second stack 210S2 may be formed by alternately stacking the first material layers 210A2 and the second material layers 210B2 on the first stack 210S1. Accordingly, the stack 210 including the first stack 210S1 and the second stack 210S2 may be formed. Here, the first material layers 210A1 and 210A2 may include an insulating material such as oxide, and the second material layers 210B1 and 210B2 may include a sacrificial material such as nitride. Therefore, the first material layers 210A1 and 210A2 may be insulating layers, and the second material layers 210B1 and 210B2 may be sacrificial layers.

Before forming the second stack 210S2, channel sacrificial layers 220S extending through the first stack 210S1 may be formed. First, first channel holes CH1 extending through the first stack 210S1 may be formed. Subsequently, channel sacrificial layers 220S may be formed in the first channel holes CH1. Here, the channel sacrificial layers 220S may include a sacrificial material. For example, the channel sacrificial layers 220S may include a sacrificial material such as tungsten or polysilicon.

Subsequently, separation sacrificial layers 230S extending through the stack 210 may be formed. For example, the separation sacrificial layers 230S may be formed in the second stack 210S2. The separation sacrificial layers 230S may mutually separate portions of the second material layers 210B2. For example, the separation sacrificial layers 230S may mutually separate portions of the second material layers 210B2 in the first direction I. The separation sacrificial layers 230S may include substantially the same material as the second material layers 210B2. For example, the separation sacrificial layers 230S may include a sacrificial material such as a nitride.

For reference, although three separation sacrificial layers 230S are shown in this drawing, the present disclosure is not limited thereto, and one separation sacrificial layer 230S may be formed in the stack 210, or two or more separation sacrificial layers 230S may be formed. In other words, the number of separation sacrificial layers 230S formed in the stack 210 is not limited.

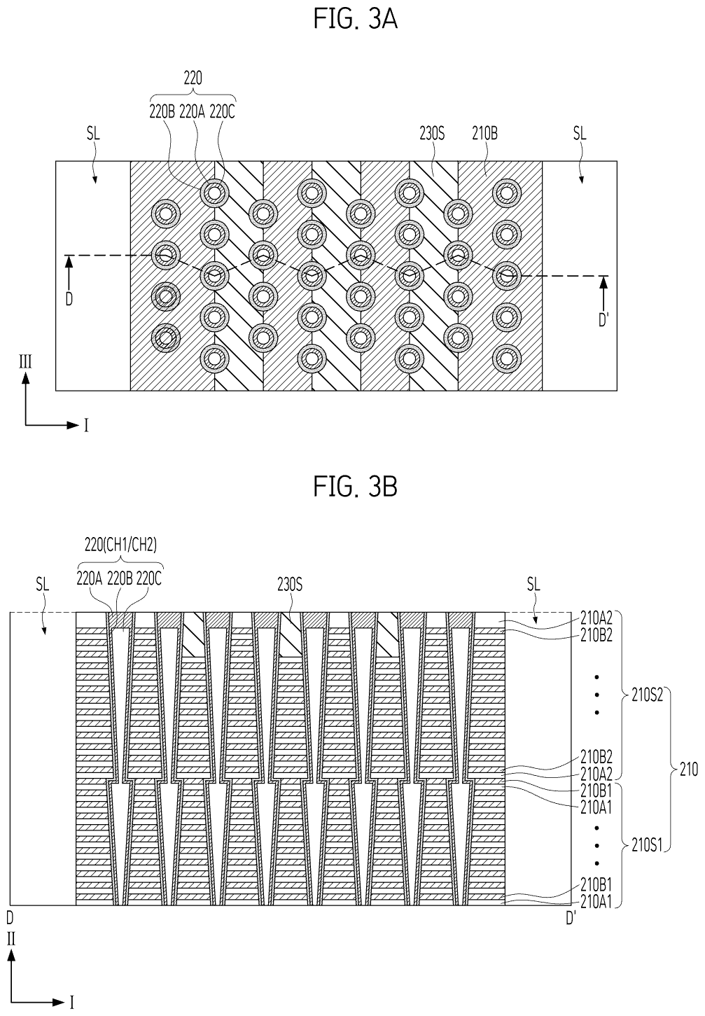

Referring to FIGS. 3A and 3B, channel structures 220 extending through the stack 210 and the separation sacrificial layers 230S may be formed. First, second channel holes CH2 extending through the second stack 210S2 (see FIG. 2B) and the separation sacrificial layers 230S and exposing the channel sacrificial layers 220S may be formed. Subsequently, the channel sacrificial layers 220S may be removed through the second channel holes CH2. Subsequently, the channel structures 220 may be formed in the second channel holes CH2 and the first channel holes CH1. Here, each of the channel structures 220 may include at least one of a channel layer 220A, a memory layer 220B surrounding the channel layer 220A, and an insulating core 220C in the channel layer 220A.

Subsequently, slits SL extending through the stack 210 may be formed. For example, the slits SL extending through the second stack 210S2 and the first stack 210S1 may be formed. The separation sacrificial layers 230S and the channel structures 220 may be positioned between the slits SL. For example, one separation sacrificial layer 230S may be positioned between the slits SL, or two or more separation sacrificial layers 230S may be positioned between the slits SL. In other words, the number of separation sacrificial layers 230S positioned between the slits SL is not limited.

Referring to FIGS. 4A to 4D, first openings OP1 may be formed by removing the second material layers 210B of the stack 210 through the slits SL. Second openings OP2 may be formed by removing the separation sacrificial layers 230S through the slits SL. Here, when removing the second material layers 210B, the separation sacrificial layers 230S may be removed. This is because the second material layers 210B and the separation sacrificial layers 230S include substantially the same material. Therefore, even though two or more separation sacrificial layers 230S are positioned between the slits SL, the second material layers 210B between the separation sacrificial layers 230S may be removed.

Subsequently, a third material layer 210C may be formed in the slits SL, the first openings OP1, and the second openings OP2. The third material layer 210C may fill the first opening OP1 and extend into the slits SL and the second openings OP2. Here, the third material layer 210C may be formed along an inner wall SL1 of the slits SL and an inner wall OP2I of the second openings OP2. The third material layers 210C may be respectively formed in the first openings OP1 (i.e., 210C (OP1)). For example, the third material layers 210C may be respectively formed in the first openings OP1 through the slits SL and the second openings OP2. Here, the third material layer 210C may include a conductive material such as tungsten. Therefore, the third material layer 210C may be a conductive layer.

Before forming the third material layer 210C, a barrier layer 210D may be formed in the slits SL, the first openings OP1, and the second openings OP2. For example, the barrier layer 210D extending into the slits SL and the second openings OP2 along an inner wall of the first openings OP1 may be formed. Here, the barrier layer 210D may be formed along the inner wall SL1 of the slits SL and the second openings OP2. The barrier layer 210D may be a metal barrier layer. The barrier layer 210D may include a metal nitride.

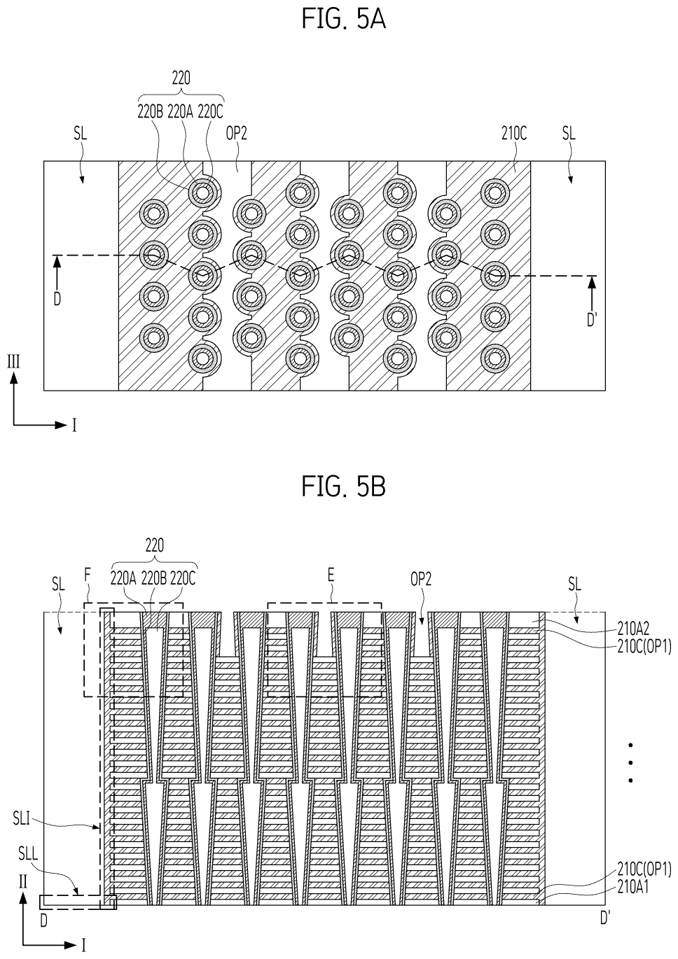

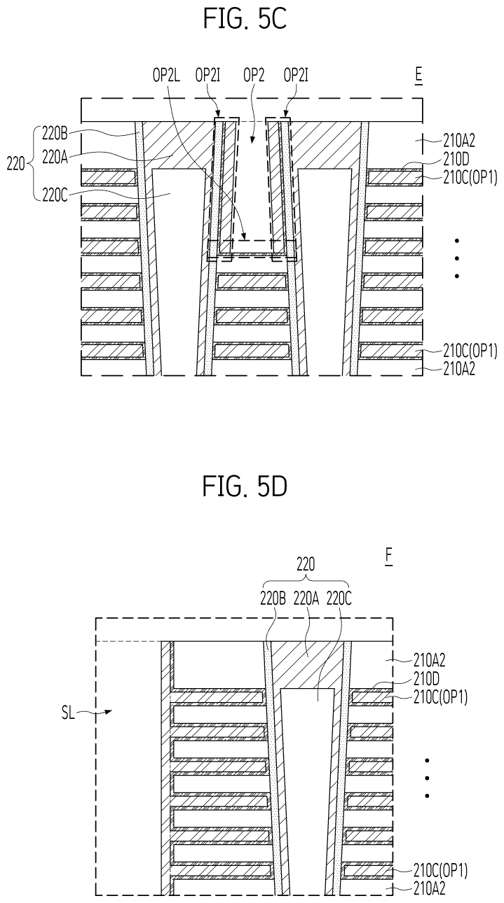

Referring to FIGS. 5A to 5D, a portion of the third material layer 210C formed on a lower surface OP2L of the second openings OP2 may be removed. In this case, the first material layer 210A2 may be exposed through the lower surface OP2L of the second openings OP2. Here, a portion of the third material layer 210C formed on an inner wall OP2I of the second openings OP2 may remain. The third material layer 210C remaining on the inner wall OP2I of the second openings OP2 may interconnect portions of the third material layers 210C formed in the first openings OP1 (i.e., 210C (OP1)). When removing a portion of the third material layer 210C formed on a lower surface OP2L of the second openings OP2, a portion of the third material layer 210C formed on a lower surface of the second openings OP2 may be removed by etching a portion of the third material layer 210C formed on a lower surface SLL of the slits SL. Here, a portion of the third material layer 210C formed on an inner wall SL1 of the slits SL may remain.

A portion of the barrier layer 210D formed on a lower surface OP2L of the second openings OP2 and a lower surface SLL of the slits SL may be removed. When removing a portion of the third material layer 210C formed on the lower surface OP2L of the second openings OP2 and the lower surface SLL of the slits SL, a portion of the barrier layer 210D formed on the lower surface OP2L of the second openings OP2 and the lower surface SLL of the slits SL may be removed. However, the present disclosure is not limited thereto, and the third material layer 210C may be first removed and then the barrier layer 210D may be removed later. In this case, after removing the barrier layer 210D, the first material layer 210A2 may be exposed through the lower surface OP2L of the second openings OP2.

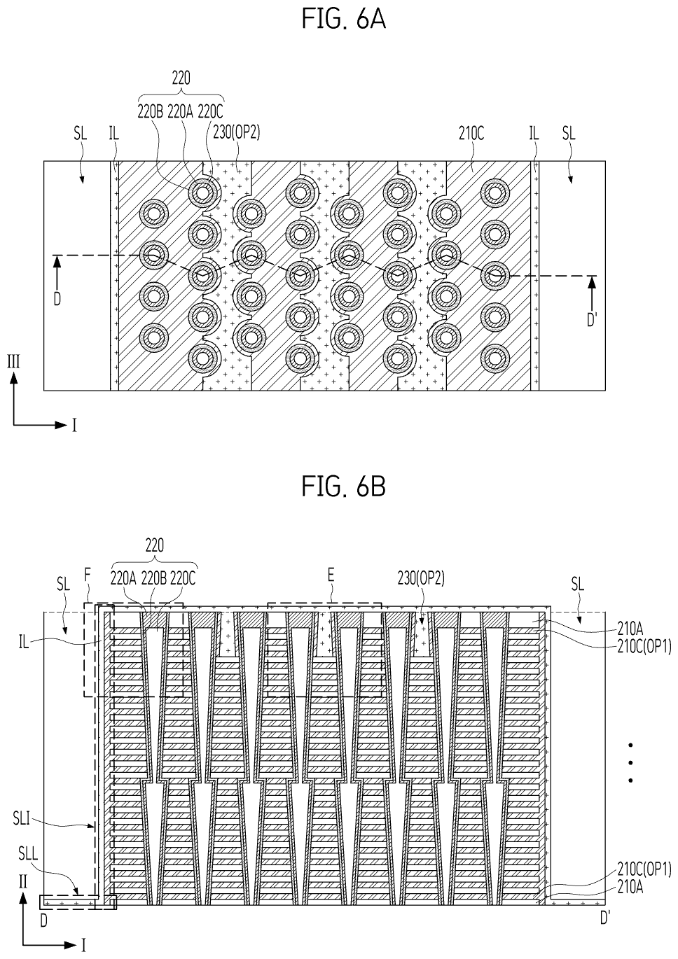

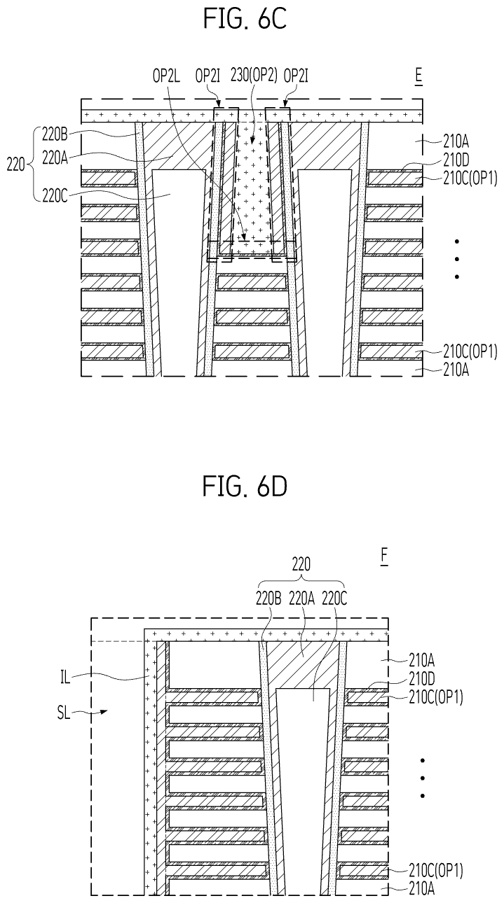

Referring to FIGS. 6A to 6D, the separation structures 230 may be formed in the second openings OP2 (i.e., 230 (OP2)). For example, the separation structures 230 may be formed by forming an insulating material to fill the second openings OP2. In this case, an insulating liner IL may be formed in the slits SL. The insulating liner IL may be formed along the inner wall SL1 of the slits SL. Therefore, the insulating liner IL may be formed on the third material layer 210C remaining on the inner wall SL1 of the slits SL. Here, the insulating material may include oxide.

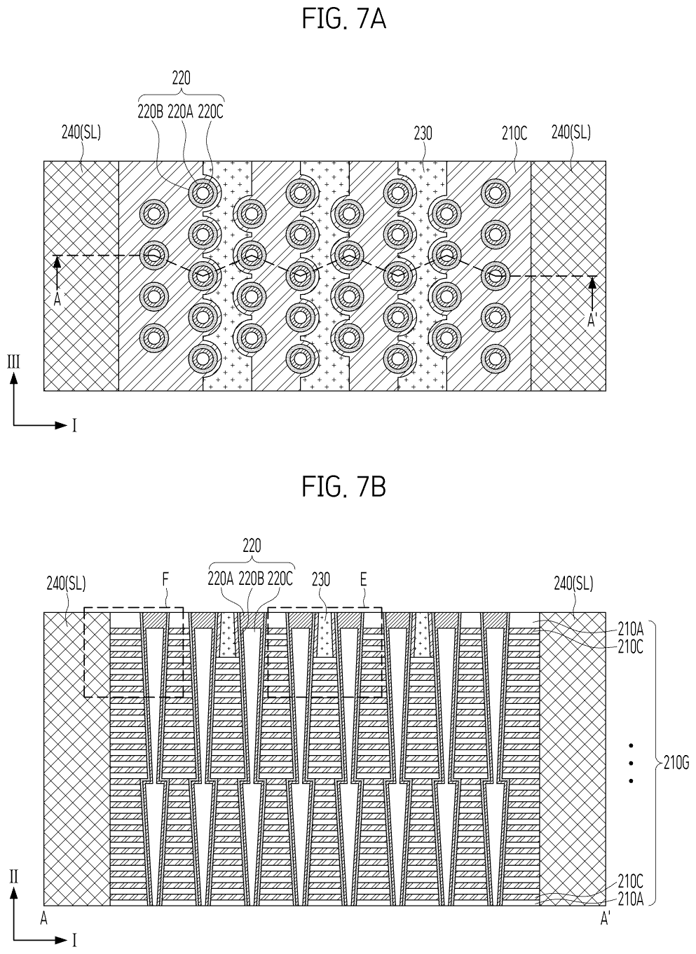

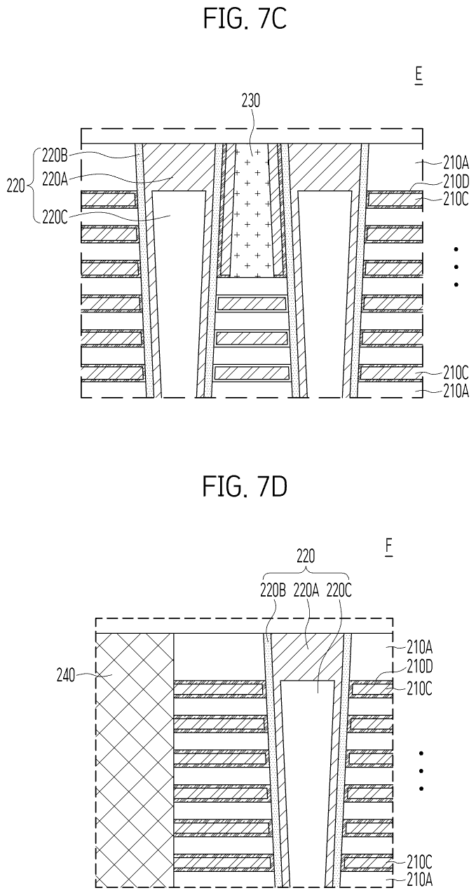

Referring to FIGS. 7A to 7D, slit structures 240 may be formed in the slits SL (i.e., 240 (SL)). First, the insulating liner IL formed along the inner wall SL1 of the slits SL may be removed. Subsequently, a portion of the third material layer 210C formed along the inner wall of the slits SL may be etched and removed. Subsequently, the slit structures 240 may be formed in the slits SL. Here, the slit structures 240 may include at least one of polysilicon, a metal, an insulating material, and a semiconductor material.

In order to form the slit structures 240, a gate structure 210G may be formed by removing the insulating liner IL and the third material layer 210C formed in the slits SL. The gate structure 210G may include first material layers 210A2 and third material layers 210C that are alternately stacked. Here, the barrier layers 210D may surround a sidewall of the third material layers 210C.

The third material layers 210C may be used as a word line, a bit line, or a select line as conductive layers. For example, among the third material layers 210C formed in the first openings OP1, the third material layers 210C that are interconnected by the third material layers 210C remaining on an inner wall of the separation structures 230 may be used as a drain select line. Remaining third material layers 210C may be used as a word line or a source select line.

According to various embodiments of manufacturing methods described above, two or more separation sacrificial layers 230S may be positioned between the slits SL. The sacrificial layers 210B and the separation sacrificial layers 230S of the stack 210 may include substantially the same sacrificial material. Therefore, the sacrificial layers 210B and the separation sacrificial layers 230S may be simultaneously removed through the slits SL, and thus a process may be unified. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

Although embodiments according to the technical spirit of the present disclosure have been described with reference to the accompanying drawings, this is only for describing an embodiment according to the concept of the present disclosure, and the present disclosure is not limited to the above-described embodiments. In the scope of the technical spirit of the present disclosure described in the claims, various forms of substitution, modification, and change of the embodiments will be possible by those skilled in the art to which the present disclosure belongs, and these also belong to the scope of the present disclosure.

What is claimed is:

1. A method of manufacturing a semiconductor device, the method comprising:
forming a stack by alternately stacking first material layers and second material layers;
forming a separation sacrificial layer extending through the stack;
forming channel structures extending through the stack and the separation sacrificial layer;
forming a slit extending through the stack;
forming first openings by removing the second material layers through the slit;
forming a second opening by removing the separation sacrificial layer through the slit;
forming third material layers in the first openings through the slit and the second opening;
forming a separation structure in the second opening; and
forming a slit structure in the slit.

2. The method of claim 1, wherein when removing the second material layers, the separation sacrificial layer is removed.

3. The method of claim 1, wherein forming the third material layers comprises:
forming a third material layer filling the first openings and extending into the slit and the second opening;
etching a portion of the third material layer formed on a lower surface of the slit and a lower surface of the second opening; and
etching a portion of the third material layer formed on an inner wall of the slit.

4. The method of claim 3, wherein when forming the separation structure, an insulating liner is formed in the slit, and the insulating liner is removed before etching a portion of the third material layer formed on the inner wall of the slit.

5. The method of claim 1, wherein the second material layers and the separation sacrificial layer include substantially the same material.

6. The method of claim 5, wherein the second material layers and the separation sacrificial layer include a nitride.

7. The method of claim 1, further comprising:
forming a barrier layer in the first openings, the slit, and the second opening, before forming the third material layers.

8. The method of claim 7, wherein the barrier layer includes a metal nitride.

9. The method of claim 1, wherein the separation structure includes an insulating material.

10. The method of claim 1, wherein forming the stack comprises:
forming a first stack;
forming first channel holes extending through the first stack; and
forming a second stack on the first stack.

11. The method of claim 10, further comprising:
forming second channel holes extending through the second stack and the separation sacrificial layer and connected to the first channel holes, after forming the separation sacrificial layer.

12. The method of claim 11, wherein forming channel structures includes forming the channel structures in the first channel holes and the second channel holes.

13. A method of manufacturing a semiconductor device, the method comprising:
forming a stack including alternately stacking sacrificial layers and insulating layers;
forming a separation sacrificial layer in the stack;
forming channel structures extending through the separation sacrificial layer and the stack;
forming a slit extending through the stack;
forming first openings by removing the sacrificial layers through the slit and forming a second opening by removing the separation sacrificial layer simultaneously;
forming a conductive layer filling the first openings and extending into the slit and the second opening;
removing a portion of the conductive layer formed on a lower surface of the second opening and a lower surface of the slit;
forming a separation structure in the second opening;
removing a portion of the conductive layer formed on an inner wall of the slit; and
forming a slit structure in the slit.

14. The method of claim 13, wherein when forming the separation structure, an insulating liner is formed in the slit, and the insulating liner is removed before removing a portion of the conductive layer formed on the inner wall of the slit.

15. The method of claim 13, wherein the sacrificial layers and the separation sacrificial layer include substantially the same material.

16. The method of claim 15, wherein the sacrificial layers and the separation sacrificial layer include a nitride.

17. The method of claim 13, further comprising:
forming a barrier layer in the first openings, the slit, and the second opening, before forming the conductive layer.

18. The method of claim 17, wherein the barrier layer includes a metal nitride.

19. The method of claim 13, wherein the separation structure includes an insulating material.

20. The method of claim 13, wherein forming the stack comprises:
forming a first stack;
forming first channel holes extending through the first stack; and
forming a second stack on the first stack.

21. The method of claim 20, further comprising:
forming second channel holes extending through the second stack and the separation sacrificial layer and connected to the first channel holes, after forming the separation sacrificial layer.

22. The method of claim 21, wherein forming the channel structures includes forming the channel structures in the first channel holes and the second channel holes.
